(19) United States
(12) Patent Application Publication
(10) Pub. No.: US 2024/0244812 A1
(43) Pub. Date: Jul. 18, 2024

(54) MOTOR CONTROL SYSTEM, CONTROL DEVICE, CONTROL METHOD, AND PROGRAM

(71) Applicant: Panasonic Intellectual Property Management Co., Ltd., Osaka (JP)

(72) Inventors: YUSUKE KUBOI, Osaka (JP); HIROSHI FUJIWARA, Osaka (JP); KENTA MURAKAMI, Osaka (JP)

(21) Appl. No.: 18/559,413

(22) PCT Filed: Apr. 11, 2022
(86) PCT No.: PCT/JP2022/017525

§ 371 Date: Nov. 7, 2023

(30) Foreign Application Priority Data
May 13, 2021 (JP) 2021-081792

(51) Int. Cl. H05K 13/04; H05K 13/08

(52) U.S. Cl. CPC H05K 13/0406; H05K 13/0812; H05K 13/082; H05K 13/087; H05K 13/0882

(57) ABSTRACT

Motor control system (10) includes position detection device (14), controller (12), and motor control device (16). Motor control device (16) includes a shift amount calculation unit that calculates a predicted arrival position of moving unit (50) based on positional information indicating a position of moving unit (50) detected by using position detection device (14) and distance information indicating a future moving distance of moving unit (50) based on an operation command, calculates a shift amount between the predicted arrival position and a target position of moving unit (50), and outputs information indicating the shift amount between the predicted arrival position and the target position. The shift amount calculation unit determines a reference point in time in consideration of at least one of an acquisition time required to acquire the positional information and an acquisition time required to acquire the distance information, acquires or calculates the position and the future moving distance of moving unit (50) at the reference point in time, and calculates the predicted arrival position based on the position and the future moving distance of moving unit (50) at the reference point in time.

### TECHNICAL FIELD

The present disclosure relates to a motor control system, a control device, a control method, and a program.

### BACKGROUND ART

In related art, a motor control system that controls a motor to move a moving unit has been known. For example, PTL 1 discloses a position control method of a motor for performing control with a schematic command value pattern and creating a correction command value pattern when a final target position is recognized while this control is being performed.

### CITATION LIST

### Patent Literature

PTL 1: Unexamined Japanese Patent Publication No. H5-297954

### SUMMARY OF THE INVENTION

However, in the position control method of PTL 1, when a time or the like required to acquire positional information of the moving unit occurs, there is a problem that a predicted arrival position of the moving unit cannot be accurately calculated and accuracy of position control deteriorates.

The present disclosure has been made to solve such a problem, and an object thereof is to provide a motor control system, a control method, a control device, and a program capable of suppressing deterioration in accuracy of position control.

A motor control system according to one aspect of the present disclosure includes a position detection device that detects a position of a moving unit that moves, a command device that outputs an operation command for operating a motor that moves the moving unit, and a control device. The control device includes a calculation unit and an output unit. The calculation unit calculates a predicted arrival position of the moving unit based on positional information indicating the position of the moving unit detected by using the position detection device and distance information indicating a future moving distance of the moving unit based on the operation command, and calculates a shift amount between the predicted arrival position and a target position of the moving unit. The output unit outputs information indicating the shift amount between the predicted arrival position and the target position calculated by the calculation unit. The calculation unit determines a reference point in time in consideration of at least one of an acquisition time required to acquire the positional information and an acquisition time required to acquire the distance information, acquires or calculates the position and the future moving distance of the moving unit at the reference point in time, and calculates the predicted arrival position based on the acquired or calculated position and future moving distance of the moving unit at the reference point in time.

A control device according to another aspect of the present disclosure includes a calculation unit and an output unit. The calculation unit calculates a predicted arrival position of a moving unit based on positional information indicating a position of the moving unit detected by using a position detection device that detects the position of the moving unit that moves and distance information indicating a future moving distance of the moving unit based on an operation command for operating a motor that moves the moving unit, and calculates a shift amount between the predicted arrival position and a target position of the moving unit. The output unit outputs information indicating the shift amount between the predicted arrival position and the target position calculated by the calculation unit. The calculation unit determines a reference point in time in consideration of at least one of an acquisition time required to acquire the positional information and an acquisition time required to acquire the distance information, acquires or calculates the position and the future moving distance of the moving unit at the reference point in time, and calculates the predicted arrival position based on the acquired or calculated position and future moving distance of the moving unit at the reference point in time.

A control method according to still another aspect of the present disclosure includes a calculation step and an output step. In the calculation step, a predicted arrival position of a moving unit is calculated based on positional information indicating a position of the moving unit detected by using a position detection device that detects the position of the moving unit and distance information indicating a future moving distance of the moving unit based on an operation command for operating a motor that moves the moving unit, and a shift amount between the predicted arrival position and a target position of the moving unit is calculated. In the output step, information indicating the shift amount between the predicted arrival position and the target position calculated in the calculation step is output. In the calculation step, a reference point in time is determined in consideration of at least one of an acquisition time required to acquire the positional information and an acquisition time required to acquire the distance information, the position of the moving unit and the future moving distance at the reference point in time are acquired or calculated, and the predicted arrival position is calculated based on the acquired or calculated position and future moving distance of the moving unit at the reference point in time.

A program according to still another aspect of the present disclosure is a program for causing a computer to execute the control method.

According to the present disclosure, it is possible to provide the motor control system and the like capable of suppressing deterioration in the accuracy of the position control.

### BRIEF DESCRIPTION OF THE DRAWINGS

FIG. 1 is a block diagram illustrating a functional configuration of a production apparatus according to an exemplary embodiment.

FIG. 2 is a block diagram illustrating a functional configuration of a second signal processing circuit included in a motor control device of the production apparatus in FIG. 1.

FIG. 3 is a diagram illustrating a schematic configuration of a moving unit of the production apparatus in FIG. 1.

FIG. 4 is a diagram illustrating a time series of information acquired in the production apparatus in FIG. 1.

FIG. 5 is a flowchart illustrating a first operation example of the second signal processing circuit of the production apparatus in FIG. 1 when a shift amount is calculated.

FIG. 6 is a flowchart illustrating the first operation example of the second signal processing circuit of the production apparatus in FIG. 1 when a reference point in time is determined.

FIG. 7 is a diagram for describing an operation example illustrated in FIGS. 5 and 6.

FIG. 8 is a flowchart illustrating a second operation example of the second signal processing circuit of the production apparatus in FIG. 1 when the reference point in time is determined.

FIG. 9 is a diagram for describing the operation example illustrated in FIGS. 5 and 8.

FIG. 10 is a diagram illustrating a schematic configuration of another moving unit.

FIG. 11 is a flowchart illustrating the second operation example of the second signal processing circuit of the production apparatus in FIG. 1 when the shift amount is calculated.

FIG. 12 is a flowchart illustrating a third operation example of the second signal processing circuit of the production apparatus in FIG. 1 when the shift amount is calculated.

FIG. 13 is a flowchart illustrating a fourth operation example of the second signal processing circuit of the production apparatus in FIG. 1 when the shift amount is calculated.

### DESCRIPTION OF EMBODIMENT

Hereinafter, exemplary embodiments of the present disclosure will be described. Note that all the exemplary embodiments to be described below show one specific example of the present disclosure. Therefore, numerical values, constituent elements, disposition positions and connection modes of the constituent elements, and steps, order of the steps, and the like illustrated in the following exemplary embodiments are merely examples, and are not intended to limit the present disclosure. Thus, among the constituent elements in the following exemplary embodiments, constituent elements that are not described in independent claims indicating the highest concept of the present disclosure are described as optional constituent elements.

In addition, each of the drawings is a schematic diagram, and is not necessarily precisely illustrated. Note that, in all the drawings, substantially the same configurations are denoted by the same reference marks, and redundant description will be omitted or simplified.

### Exemplary Embodiment

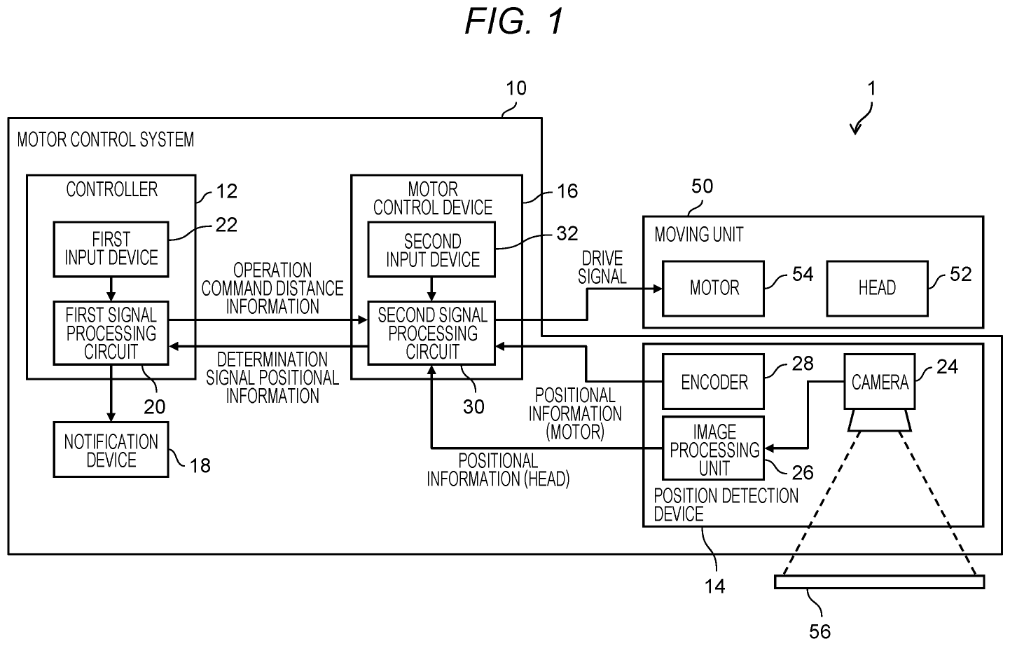

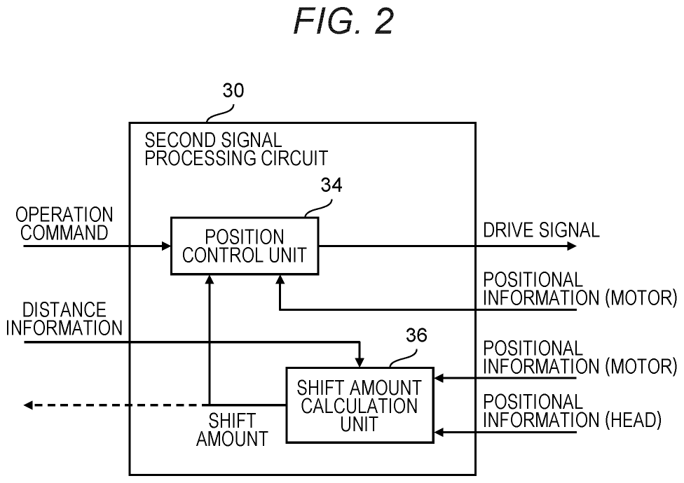

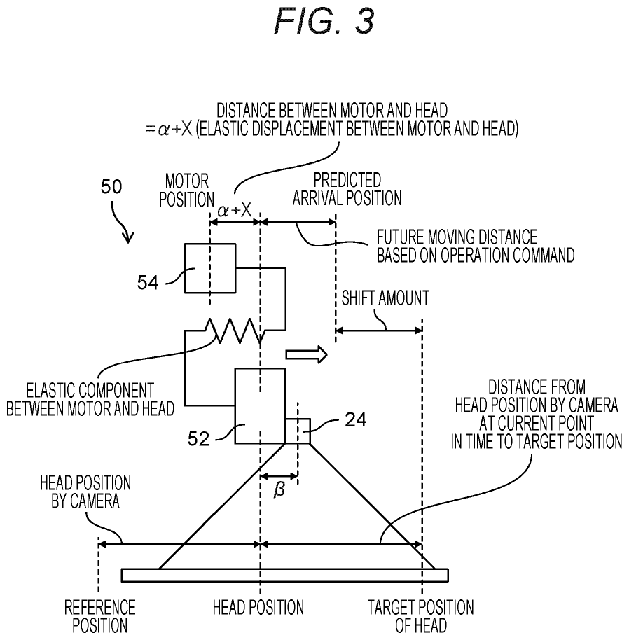

FIG. 1 is a block diagram illustrating a functional configuration of production apparatus 1 according to an exemplary embodiment. FIG. 2 is a block diagram illustrating a functional configuration of second signal processing circuit 30 included in motor control device 16 of production apparatus 1 in FIG. 1. FIG. 3 is a diagram illustrating a schematic configuration of moving unit 50 of production apparatus 1 in FIG. 1.

As illustrated in FIGS. 1 and 2, production apparatus 1 includes motor control system 10 and moving unit 50. Moving unit 50 includes head 52 that holds an object and motor 54 that is coupled to head 52 and moves together with head 52. Motor 54 is a drive source for moving head 52. Production apparatus 1 performs production by using motor 54. For example, production apparatus 1 is a mounting machine that moves an electronic component (not illustrated) attracted and held by head 52 onto printed wiring substrate 56 together with head 52 by using motor 54, and mounts the electronic component at a predetermined position on printed wiring substrate 56.

Motor control system 10 is a system that controls motor 54. For example, motor control system 10 controls a position and the like of motor 54. Motor control system 10 includes controller 12, position detection device 14, motor control device 16, and notification device 18.

Controller 12 is an example of a command device that outputs an operation command for operating a motor that moves moving unit 50. Controller 12 includes first signal processing circuit 20 and a first input device 22.

First signal processing circuit 20 is a circuit that performs signal processing. First signal processing circuit 20 generates an operation command and outputs the generated operation command. For example, the operation command is a position command indicating a moving distance (moving amount) or the like for moving moving unit 50. In addition, for example, the operation command is a speed command indicating a moving speed or the like for moving moving unit 50.

In first signal processing circuit 20, an operation command plan is set for a movement plan during a period until moving unit 50 arrives at a target position from an initial position.

For example, the movement plan is set in first signal processing circuit 20 by being input by an operator of controller 12 by using first input device 22. For example, the operation command plan is a plan that defines a content of the operation command, an output timing of the operation command, and the like in order to move moving unit 50 along the movement plan. For example, first signal processing circuit 20 generates the operation command plan based on the set movement plan, and stores the operation command plan in memory 121 in controller 12. For example, first signal processing circuit 20 moves moving unit 50 along the movement plan by repeatedly outputting one or more operation commands based on the operation command plan.

First signal processing circuit 20 calculates a future moving distance of moving unit 50 based on the operation command, and outputs distance information indicating the calculated future moving distance. For example, the future moving distance based on the operation command is a moving distance of moving unit 50 based on the operation command output from first signal processing circuit 20 in the future. For example, the operation command to be output from first signal processing circuit 20 in the future is an operation command that has not yet been output from first signal processing circuit 20 among all the operation commands included in the operation command plan. For example, the moving distance of moving unit 50 based on the operation command already output from first signal processing circuit 20 is subtracted from the moving distance of moving unit 50 based on all the operation commands included in the operation command plan, and thus, the moving distance of moving unit 50 based on the operation command output from first signal processing circuit 20 in the future can be calculated. Note that, for example, second signal processing circuit 30 included in motor control device 16 may calculate the future moving distance of moving unit 50 based on the operation command.

First signal processing circuit 20 receives a determination signal and the like from motor control device 16. The determination signal is a signal indicating a determination result on a shift amount between a predicted arrival position of moving unit 50 and a target position of moving unit 50. First signal processing circuit 20 controls notification device 18 based on the determination signal. For example, in a case where the shift amount between the predicted arrival position of moving unit 50 and the target position of moving unit 50 is equal to or more than a predetermined threshold, first signal processing circuit 20 generates and outputs a notification signal, and causes notification device 18 to perform notification.

For example, first signal processing circuit 20 is a computer, and the processing of first signal processing circuit 20 can be implemented by program processing in the computer.

First input device 22 is a device that receives an input operation by the operator or the like. For example, as described above, first input device 22 receives the input operation of the movement plan. For example, first input device 22 can be implemented by a touch panel, a hardware button, or the like.

Position detection device 14 is a device for detecting a position of moving unit 50 that moves. Position detection device 14 includes camera 24, image processing unit 26, and encoder 28.

Camera 24 and image processing unit 26 are devices for detecting a position of head 52 in moving unit 50. Camera 24 is coupled to head 52 and moves with head 52. Image processing unit 26 processes an image imaged by camera 24 and calculates the position of head 52. For example, in a case where the target position appears in the image imaged by camera 24, image processing unit 26 calculates a distance from head 52 to the target position by analyzing the image. Image processing unit 26 outputs positional information indicating the position of head 52.

Encoder 28 is a device for detecting a position of motor 54 in moving unit 50. Encoder 28 is coupled to motor 54 and moves together with motor 54. For example, encoder 28 detects the position of motor 54 by reading a linear scale (not illustrated). Encoder 28 outputs positional information indicating the position of motor 54.

Note that, for example, image processing unit 26 may be included in second signal processing circuit 30 or the like included in motor control device 16.

Motor control device 16 is an example of a control device that calculates the predicted arrival position of moving unit 50 based on the positional information indicating the position of moving unit 50 detected by using position detection device 14 and distance information indicating the future moving distance of moving unit 50 based on the operation command and calculates and outputs the shift amount between the predicted arrival position of moving unit 50 and the target position of moving unit 50. Motor control device 16 includes second signal processing circuit 30 and second input device 32.

Second signal processing circuit 30 is a circuit that performs signal processing. As illustrated in FIG. 2, second signal processing circuit 30 includes position control unit 34 and shift amount calculation unit 36.

Position control unit 34 generates a drive signal for driving motor 54 based on the operation command output from controller 12, the positional information indicating the position of motor 54 detected by using encoder 28, and the shift amount between the predicted arrival position of moving unit 50 and the target position of moving unit 50 output from shift amount calculation unit 36, and outputs the generated drive signal.

Shift amount calculation unit 36 is an example of a calculation unit that calculates the shift amount between the predicted arrival position of moving unit 50 and the target position of moving unit 50. In addition, shift amount calculation unit 36 is an example of an output unit that outputs information indicating the shift amount between the predicted arrival position of moving unit 50 and the target position of moving unit 50 calculated by shift amount calculation unit 36.

Shift amount calculation unit 36 calculates the predicted arrival position of moving unit 50 based on the positional information indicating the position of moving unit 50 detected by using position detection device 14 and the distance information indicating the future moving distance of moving unit 50 based on the operation command. The predicted arrival position of moving unit 50 is a position where moving unit 50 is predicted to arrive.

The positional information of moving unit 50 detected by using position detection device 14 includes the positional information indicating the position of head 52 detected by using camera 24 and the positional information indicating the position of motor 54 detected by using encoder 28. For example, the position of head 52 is calculated by the position of camera 24 with respect to the target position and a distance (see ß in FIG. 3) between the position of camera 24 and the position of head 52.

For example, shift amount calculation unit 36 calculates the predicted arrival position of moving unit 50 based on the positional information indicating the position of motor 54 detected by using encoder 28 and the distance information indicating the future moving distance of moving unit 50 based on the operation command. Specifically, for example, as illustrated in FIG. 3, shift amount calculation unit 36 calculates the predicted arrival position of moving unit 50 by using the position of motor 54 detected by using encoder 28, a distance between the position of motor 54 and the position of head 52 (see α+X in FIG. 3), and the future moving distance of moving unit 50 based on the operation command.

Note that, although details will be described later, shift amount calculation unit 36 calculates the predicted arrival position of moving unit 50 in consideration of an acquisition time required to acquire the positional information indicating the position of moving unit 50 detected by using position detection device 14 and an acquisition time required to acquire the distance information indicating the future moving distance of moving unit 50 based on the operation command.

Shift amount calculation unit 36 calculates the shift amount between the calculated predicted arrival position of moving unit 50 and the target position of moving unit 50, and outputs information indicating the shift amount. In addition, shift amount calculation unit 36 determines whether or not the calculated shift amount is equal to or more than a predetermined threshold, and outputs a determination signal indicating a determination result. For example, the determination signal output from shift amount calculation unit 36 is input to position control unit 34, but may be input to first signal processing circuit 20.

For example, second signal processing circuit 30 is a computer, and the processing of position control unit 34 and shift amount calculation unit 36 can be implemented by program processing in the computer.

Notification device 18 is connected to controller 12. For example, notification device 18 is a display unit. In this case, notification device 18 displays a warning indicating that the shift amount between the predicted arrival position of moving unit 50 and the target position of moving unit 50 is equal to or more than the predetermined threshold based on the notification signal output from controller 12.

Note that, for example, notification device 18 may be a warning lamp. In this case, notification device 18 turns on the warning lamp based on the notification signal output from controller 12. Note that, for example, notification device 18 may not be connected to controller 12, but may be connected to motor control device 16. In addition, notification device 18 may be included in controller 12 or motor control device 16.

With notification device 18, a subject (for example, including a worker who uses production apparatus 1 or a manager and a maintenance person of production apparatus 1) involved in production apparatus 1 (motor control system 10) can easily and quickly grasp that a position deviation between the predicted arrival position of moving unit 50 and the target position of moving unit 50 is equal to or more than a predetermined threshold.

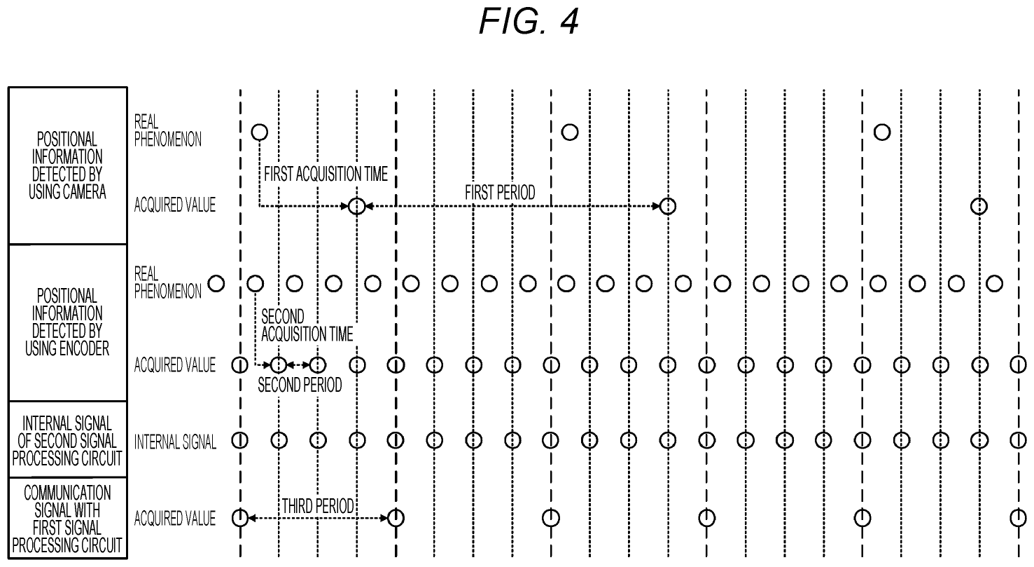

FIG. 4 is a diagram illustrating a time series of information acquired in production apparatus 1 in FIG. 1.

As illustrated in FIG. 4, the position of moving unit 50 is periodically detected by using position detection device 14, and shift amount calculation unit 36 periodically acquires the positional information indicating the position of moving unit 50 detected by using position detection device 14.

Specifically, the position of head 52 is detected in a first period by using camera 24, and shift amount calculation unit 36 acquires the positional information indicating the position of head 52 in the first period.

Note that, until shift amount calculation unit 36 acquires the positional information, an acquisition time including a time required for image processing by image processing unit 26, a time required for transmitting the positional information, and the like may occur. In the following description, the acquisition time may be referred to as a first acquisition time. That is, the position of head 52 indicated by the positional information acquired by shift amount calculation unit 36 is a position where head 52 is actually positioned at a point in time earlier by the first acquisition time from a point in time at which the positional information is acquired.

In addition, the position of motor 54 is detected in a second period by using encoder 28, and shift amount calculation unit 36 acquires the positional information indicating the position of motor 54 in the second period.

Note that, until shift amount calculation unit 36 acquires the positional information, an acquisition time including the time required for transmitting the positional information and the like may occur. In the following description, the acquisition time may be referred to as a second acquisition time. That is, the position of motor 54 indicated by the positional information acquired by shift amount calculation unit 36 is a position where motor 54 is actually positioned at a point in time earlier by the second acquisition time from a point in time at which the positional information is acquired.

First signal processing circuit 20 periodically calculates the future moving distance of moving unit 50 based on the operation command, and shift amount calculation unit 36 periodically acquires the distance information indicating the future moving distance of moving unit 50 based on the operation command calculated by first signal processing circuit 20.

Specifically, first signal processing circuit 20 calculates the future moving distance of moving unit 50 based on the operation command in a third period, and shift amount calculation unit 36 acquires the distance information indicating the future moving distance of moving unit 50 based on the operation command in the third period.

Note that, although until shift amount calculation unit 36 acquires the distance information, an acquisition time including the time required for transmitting the distance information and the like may occur, since the acquisition time is minute, the acquisition time is not considered here. Note that shift amount calculation unit 36 may consider the acquisition time.

Shift amount calculation unit 36 (second signal processing circuit 30) periodically acquires an internal signal or the like, periodically calculates the predicted arrival position of moving unit 50, and periodically calculates the shift amount between the predicted arrival position of moving unit 50 and the target position of moving unit 50. Here, shift amount calculation unit 36 calculates the shift amount whenever the positional information indicating the position of motor 54 detected by using encoder 28 is acquired, that is, in the second period.

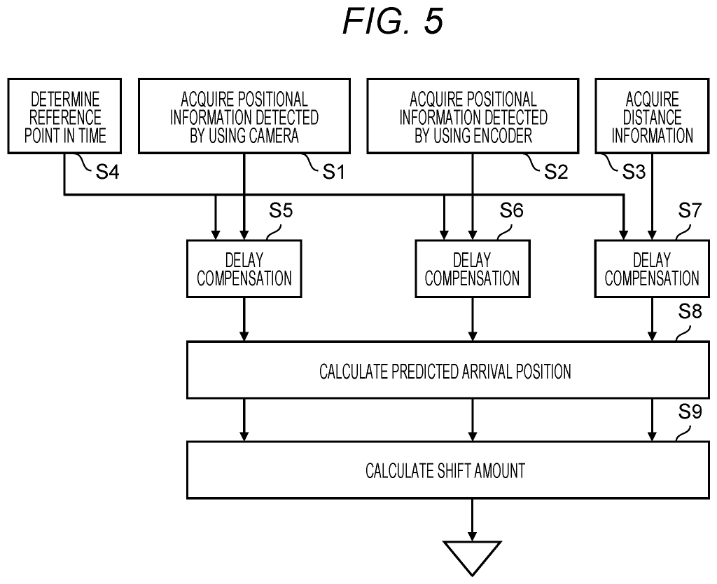

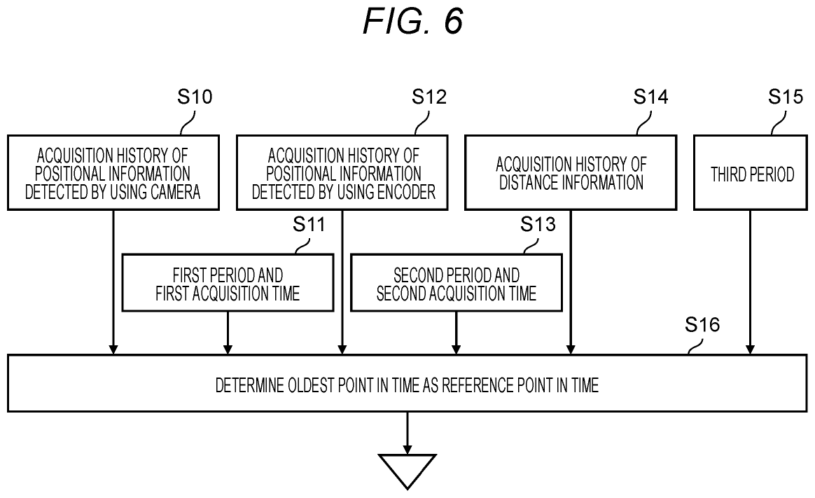

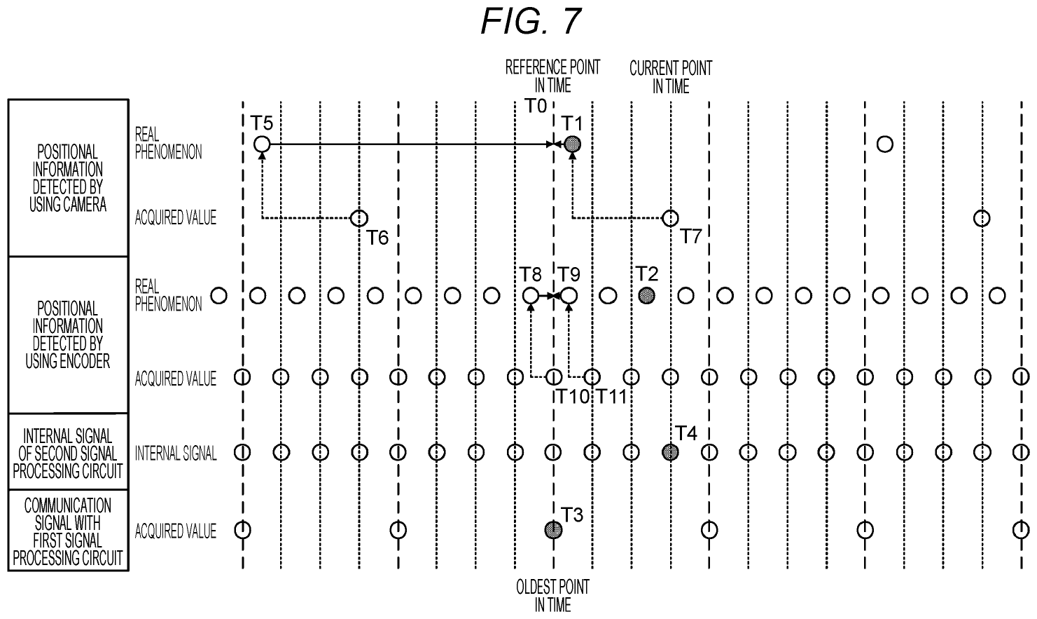

FIG. 5 is a flowchart illustrating a first operation example of shift amount calculation unit 36 of production apparatus 1 in FIG. 1 when the shift amount is calculated. FIG. 6 is a flowchart illustrating a first operation example of shift amount calculation unit 36 of production apparatus 1 in FIG. 1 when a reference point in time is determined. FIG. 7 is a diagram for describing the operation example illustrated in FIGS. 5 and 6.

As illustrated in FIG. 5, shift amount calculation unit 36 acquires the positional information indicating the position of head 52 detected by using camera 24 (step S1), acquires the positional information indicating the position of motor 54 detected by using encoder 28 (step S2), and acquires the distance information indicating the future moving distance of moving unit 50 based on the operation command (step S3).

In addition, shift amount calculation unit 36 determines the reference point in time in consideration of the first acquisition time and the second acquisition time (step S4).

As illustrated in FIG. 6, for example, shift amount calculation unit 36 acquires an acquisition history of the positional information indicating the position of head 52 detected by using camera 24 (step S10), and acquires the first period and the first acquisition time (step S11). In addition, shift amount calculation unit 36 acquires an acquisition history of the positional information indicating the position of motor 54 detected by using encoder 28 (step S12), and acquires the second period and the second acquisition time (step S13). In addition, shift amount calculation unit 36 acquires an acquisition history of the distance information indicating the future moving distance of moving unit 50 based on the operation command (step S14), and acquires the third period (step S15).

In consideration of the acquired first acquisition time and the like, shift amount calculation unit 36 determines, as the reference point in time, an oldest point in time of a point in time earlier by the acquisition time required to acquire the positional information from a point in time at which latest positional information among a plurality of pieces of periodically acquired positional information is acquired and a point in time at which latest distance information among a plurality of pieces of periodically acquired distance information is acquired (step S16).

For example, in FIG. 7, a point in time earlier by the first acquisition time from a point in time at which latest positional information before a current point in time is acquired among a plurality of pieces of positional information indicating the position of head 52 detected by using camera 24 is set as T1. In addition, a point in time earlier by the second acquisition time from a point in time at which latest positional information before a current point in time is acquired among a plurality of pieces of positional information indicating the position of motor 54 detected by using encoder 28 is set as T2. In addition, a point in time at which latest distance information before a current point in time is acquired among the plurality of pieces of distance information acquired from first signal processing circuit 20 is set as T3. In addition, a point in time at which latest internal signal before a current point in time is acquired among internal signals of shift amount calculation unit 36 (first signal processing circuit 20) is set as T4.

For example, shift amount calculation unit 36 determines an oldest point in time among T1, T2, and T3. Here, the oldest point in time among T1, T2, and T3 is T3. Therefore, shift amount calculation unit 36 determines T3 as the reference point in time.

Referring back to FIG. 5, when the reference point in time is determined, shift amount calculation unit 36 performs delay compensation on the positional information indicating the position of moving unit 50 detected by using position detection device 14 (steps S5 and S6). For example, shift amount calculation unit 36 acquires or calculates the position of moving unit 50 at the reference point in time in consideration of the acquisition time required to acquire the positional information as the delay compensation.

For example, shift amount calculation unit 36 calculates the position of moving unit 50 at the reference point in time by using the positional information acquired at a point in time later by the acquisition time from a first point in time and the positional information acquired at a point in time later by the acquisition time from a second point in time. Here, the first point in time is a latest point in time before the reference point in time among a plurality of point in times earlier by the acquisition time required to acquire the positional information from each of a plurality of point in times at which the plurality of periodically acquired positional information are acquired. The second point in time is an oldest time after the reference point in time among a plurality of point in times earlier by the acquisition time required to acquire the positional information from each of a plurality of point in times at which the plurality of pieces of periodically acquired positional information are acquired.

Here, shift amount calculation unit 36 acquires or calculates the position of head 52 at the reference point in time as the delay compensation (step S5), and acquires or calculates the position of motor 54 at the reference point in time as the delay compensation (step S6).

As illustrated in FIG. 7, here, the reference point in time is TO, a latest first point in time before the reference point in time among a plurality of point in times earlier by the first acquisition time from each of a plurality of point in times at which the plurality of pieces of positional information detected by using camera 24 are acquired is T5, and an oldest second point in time after the reference point in time among a plurality of point in times earlier by the first acquisition time from each of a plurality of point in times at which the plurality of pieces of positional information detected by using camera 24 are acquired is T1. In addition, here, a point in time later by the first acquisition time from the first point in time is T6, and a point in time later by the first acquisition time from the second point in time is T7. In this case, when a difference between the reference point in time and the first point in time is ΔT1, ΔT1=T0−T5 is obtained. In addition, when a difference between the second point in time and the reference point in time is ΔT2, ΔT2=T1−T0 is obtained.

For example, in a case where the position of moving unit 50 indicated by the positional information acquired at T6 is X and the position of moving unit 50 indicated by the positional information acquired at T7 is Y, shift amount calculation unit 36 calculates the position of head 52 at the reference point in time by ΔT2/(ΔT1+ΔT2)×X+ΔT1/(ΔT1+ΔT2)×Y.

In addition, here, the reference point in time is TO, a latest first point in time before the reference point in time among a plurality of point in times earlier by the second acquisition time from each of a plurality of point in times at which the plurality of pieces of positional information detected by using encoder 28 are acquired is T8, and an oldest second point in time after the reference point in time among a plurality of point in times earlier by the second acquisition time from each of a plurality of point in times at which the plurality of pieces of positional information detected by using encoder 28 are acquired is T9. In addition, here, a point in time later by the second acquisition time from the first point in time is set as T10, and a point in time later by the second acquisition time from the second point in time is set as T11. In this case, when a difference between the reference point in time and the first point in time is ΔT3, ΔT3=T0−T8 is obtained. In addition, when a difference between the second point in time and the reference point in time is ΔT4, ΔT4=T9−T0 is obtained.

For example, in a case where the position of motor 54 indicated by the positional information acquired at T10 is X1 and the position of motor 54 indicated by the positional information acquired at T11 is Y1, shift amount calculation unit 36 calculates the position of motor 54 at the reference point in time by ΔT4/(ΔT3+ΔT4)×X1+ΔT3/(ΔT3+ΔT4)×Y1.

Referring back to FIG. 5, shift amount calculation unit 36 similarly performs the delay compensation on the future moving distance of moving unit 50 based on the operation command (step S7). For example, shift amount calculation unit 36 acquires or calculates the future moving distance of moving unit 50 at the reference point in time in consideration of the first acquisition time and the second acquisition time as the delay compensation.

Here, since the reference point in time is T3 and there is the distance information indicating the future moving distance of moving unit 50 at T3, shift amount calculation unit 36 acquires the future moving distance of moving unit 50 at the reference point in time.

When the position of moving unit 50 and the future moving distance of moving unit 50 are acquired or calculated at the reference point in time, shift amount calculation unit 36 calculates the predicted arrival position of moving unit 50 by using the acquired or calculated position of moving unit 50 and future moving distance of moving unit 50 at the reference point in time (step S8).

For example, shift amount calculation unit 36 calculates the predicted arrival position of moving unit 50 by using the position of motor 54 detected by using encoder 28, the distance (see α+X in FIG. 3) between the position of motor 54 and the position of head 52, and the future moving distance of moving unit 50.

When the predicted arrival position of moving unit 50 is calculated, shift amount calculation unit 36 calculates the shift amount between the predicted arrival position of moving unit 50 and the target position of moving unit 50 (step S9). For example, a difference between the predicted arrival position and the target position is calculated as the shift amount.

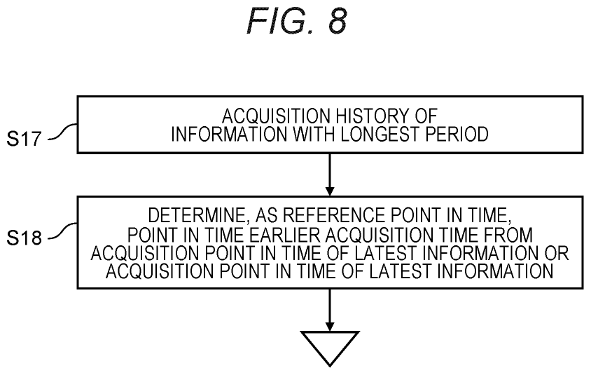

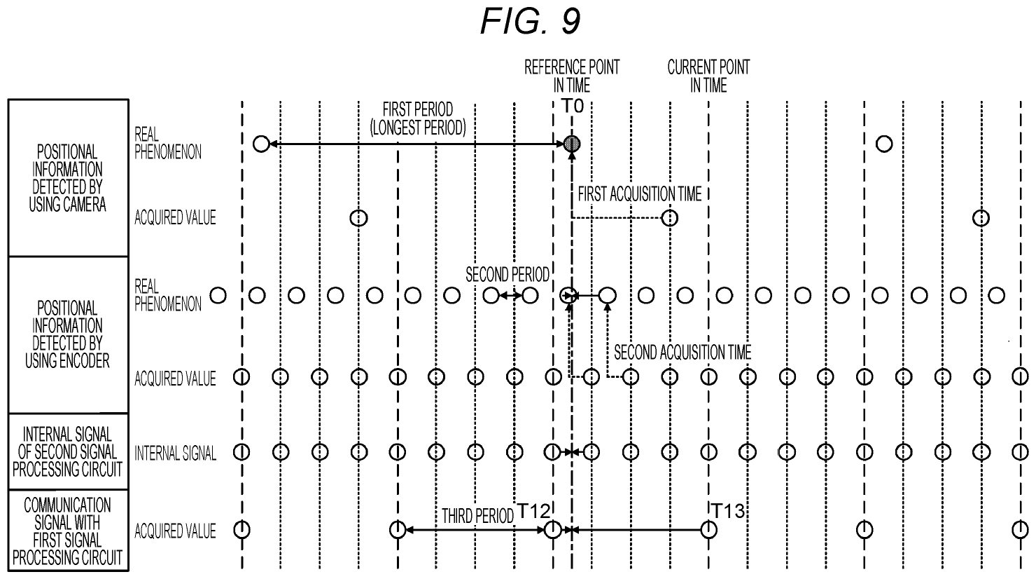

FIG. 8 is a flowchart illustrating a second operation example of shift amount calculation unit 36 of production apparatus 1 in FIG. 1 when the reference point in time is determined. FIG. 9 is a diagram for describing the operation example illustrated in FIGS. 5 and 8.

As illustrated in FIG. 8, shift amount calculation unit 36 may acquire an acquisition history of information having a longest period among the periodically acquired positional information and distance information (step S17), and may determine, as the reference point in time, a point in time at which latest information among pieces of information included in the acquisition history is acquired or a point in time earlier by an acquisition time required to acquire the information from a point in time at which the latest information is acquired (step S18).

That is, for example, in a case where a period of acquiring the positional information is longer than a period of acquiring the distance information, shift amount calculation unit 36 determines, as the reference point in time, a point in time earlier by the first acquisition time from a point in time at which latest positional information among a plurality of pieces of periodically acquired positional information is acquired. In addition, for example, in a case where a period of acquiring the distance information is longer than a period of acquiring the positional information, shift amount calculation unit 36 determines, as the reference point in time, a point in time at which latest distance information among a plurality of pieces of periodically acquired distance information is acquired.

As illustrated in FIG. 9, here, since the first period is longer than the second period and the third period, shift amount calculation unit 36 determines, as the reference point in time, a point in time earlier by the first acquisition time from a point in time at which latest positional information among a plurality of pieces of positional information detected and periodically acquired by using camera 24 is acquired.

Then, shift amount calculation unit 36 acquires or calculates the position of moving unit 50 and the future moving distance of moving unit 50 at the reference point in time by the method described in the first operation example.

Here, since there is the positional information indicating the position of head 52 at the reference point in time, shift amount calculation unit 36 acquires the positional information and acquires the position of head 52 at the reference point in time.

In addition, here, since there is no distance information indicating the future moving distance of moving unit 50 at the reference point in time, shift amount calculation unit 36 calculates the future moving distance of moving unit 50 at the reference point in time. Specifically, for example, shift amount calculation unit 36 calculates the future moving distance at the reference point in time by using a latest third point in time before the reference point in time and an oldest fourth point in time after the reference point in time among a plurality of point in times at which a plurality of periodically acquired distance information are acquired, and the distance information acquired at the third point in time and the distance information acquired at the fourth point in time.

Here, the reference point in time is TO, the latest third point in time before the reference point in time among the plurality of point in times at which the plurality of pieces of distance information are acquired is T12, and the oldest fourth point in time after the reference point in time among the plurality of point in times at which the plurality of pieces of distance information are acquired is T13. In this case, when a difference between the reference point in time and the third point in time is ΔT5, ΔT5=T0−T12 is obtained. In addition, when a difference between the fourth point in time and the reference point in time is ΔT6, ΔT6=T13−T0 is obtained.

For example, in a case where the future moving distance of moving unit 50 indicated by the positional information acquired at T12 is X2 and the future moving distance of moving unit 50 indicated by the positional information acquired at T13 is Y2, shift amount calculation unit 36 calculates the future moving distance of moving unit 50 at the reference point in time by ΔT6/(ΔT5+ΔT6)×X2+ΔT5/(ΔT5+ΔT6)×Y2.

For example, shift amount calculation unit 36 similarly calculates the position of motor 54 at the reference point in time and an internal signal value at the reference point in time.

Note that, for example, in a case where the third period is longer than the first period and the second period, shift amount calculation unit 36 may determine, as the reference point in time, a point in time at which latest distance information among a plurality of pieces of periodically acquired distance information is acquired.

Motor control system 10 according to the exemplary embodiment has been described above.

Motor control system 10 according to the exemplary embodiment includes motor 54, moving unit 50, position detection device 14 for detecting the position of moving unit 50, controller 12 for outputting the operation command for moving moving unit 50, and motor control device 16. Motor control device 16 includes shift amount calculation unit 36. Shift amount calculation unit 36 calculates the predicted arrival position of moving unit 50 based on the positional information indicating the position of moving unit 50 detected by using position detection device 14 and the distance information indicating the future moving distance of moving unit 50 based on the operation command, calculates the shift amount between the predicted arrival position and the target position of moving unit 50, and outputs the information indicating the shift amount between the calculated predicted arrival position and the target position. In addition, shift amount calculation unit 36 determines the reference point in time in consideration of at least one of the acquisition time required to acquire the positional information and the acquisition time required to acquire the distance information, acquires or calculates the position and the future moving distance of moving unit 50 at the reference point in time, and calculates the predicted arrival position based on the acquired or calculated position and future moving distance of moving unit 50 at the reference point in time.

Accordingly, shift amount calculation unit 36 determines the reference point in time in consideration of at least one of the acquisition time required to acquire the positional information and the acquisition time required to acquire the distance information, and calculates the predicted arrival position based on the acquired or calculated position and future moving distance of moving unit 50 at the reference point in time. Here, in a case where the acquisition time required to acquire the positional information occurs, a point in time at which the positional information is acquired may be different from a point in time at which moving unit 50 is actually positioned at the position indicated by the positional information. Therefore, when the predicted arrival position is calculated on the assumption that moving unit 50 is actually positioned at the position indicated by the positional information at a point in time at which the positional information is acquired without considering the acquisition time required to acquire the positional information, the predicted arrival position cannot be accurately calculated. The same applies to the distance information. As described above, since shift amount calculation unit 36 determines the reference point in time in consideration of at least one of the acquisition time required to acquire the positional information and the acquisition time required to acquire the distance information, and calculates the predicted arrival position based on the position and the future moving distance of moving unit 50 at the reference point in time, the predicted arrival position can be accurately calculated. Therefore, since the shift amount between the predicted arrival position of moving unit 50 and the target position of moving unit 50 can be accurately calculated, moving unit 50 can be easily positioned at the target position, and deterioration in accuracy of the position control can be suppressed.

In addition, in motor control system 10 according to the exemplary embodiment, shift amount calculation unit 36 periodically acquires the positional information and the distance information, and determines, as the reference point in time, the oldest point in time of the point in time earlier by the acquisition time required to acquire the positional information from the point in time at which the latest positional information among the plurality of pieces of periodically acquired positional information is acquired and the point in time at which the latest distance information among the plurality of pieces of periodically acquired distance information is acquired.

Accordingly, since there is information at the reference point in time for one of the positional information and the distance information, the position or the future moving distance of moving unit 50 at the reference point in time can be acquired. In addition, since there are pieces of information before and after the reference point in time for the other of the positional information and the distance information, the position or the future moving distance of moving unit 50 at the reference point in time can be accurately calculated by using these pieces of information. Therefore, since the shift amount between the predicted arrival position of moving unit 50 and the target position of moving unit 50 at the reference point in time can be accurately calculated, moving unit 50 can be easily positioned at the target position, and the deterioration in the accuracy of the position control can be suppressed.

In addition, in motor control system 10 according to the exemplary embodiment, shift amount calculation unit 36 periodically acquires the positional information and the distance information. Then, in a case where the period of acquiring the positional information is longer than the period of acquiring the distance information, shift amount calculation unit 36 determines, as the reference point in time, the point in time earlier by the acquisition time required to acquire the positional information from the point in time at which the latest positional information among the plurality of pieces of periodically acquired positional information is acquired. In addition, in a case where the period of acquiring the distance information is longer than the period of acquiring the positional information, shift amount calculation unit 36 determines, as the reference point in time, the point in time at which the latest distance information among the plurality of pieces of periodically acquired distance information is acquired.

Accordingly, since there is information at the reference point in time for one of the positional information and the distance information, the position or the future moving distance of moving unit 50 at the reference point in time can be acquired. In addition, since the information is acquired in a period shorter than a period of the one for the other of the positional information and the distance information, the position or the future moving distance of moving unit 50 at the reference point in time can be accurately calculated by using information near the reference point in time. Therefore, since the shift amount between the predicted arrival position of moving unit 50 and the target position of moving unit 50 at the reference point in time can be accurately calculated, moving unit 50 can be easily positioned at the target position, and the deterioration in the accuracy of the position control can be suppressed.

In addition, in motor control system 10 according to the exemplary embodiment, shift amount calculation unit 36 periodically acquires the positional information, and calculates the position of moving unit 50 at the reference point in time by using the first point in time and the second point in time, the positional information acquired at the point in time later by the acquisition time from the first point in time and the positional information acquired at the point in time later by the acquisition time from the second point in time. Here, the first point in time is a latest point in time before the reference point in time among a plurality of point in times earlier by the acquisition time required to acquire the positional information from each of a plurality of point in times at which the plurality of periodically acquired positional information are acquired. In addition, the second point in time is an oldest point in time after the reference point in time among a plurality of point in times earlier by the acquisition time required to acquire the positional information from each of a plurality of point in times at which the plurality of periodically acquired positional information are acquired.

Accordingly, the position of moving unit 50 at the reference point in time can be accurately calculated by using the pieces of positional information before and after the reference point in time. Therefore, since the shift amount between the predicted arrival position of moving unit 50 and the target position of moving unit 50 at the reference point in time can be accurately calculated, moving unit 50 can be easily positioned at the target position, and the deterioration in the accuracy of the position control can be suppressed.

In addition, in motor control system 10 according to the exemplary embodiment, shift amount calculation unit 36 periodically acquires the distance information, and calculates the future moving distance at the reference point in time by using the latest third point in time before the reference point in time and the oldest fourth point in time after the reference point in time among the plurality of point in times at which the plurality of pieces of periodically acquired distance information are acquired, and the distance information acquired at the third point in time and the distance information acquired at the fourth point in time.

Accordingly, the future moving distance at the reference point in time can accurately be calculated by using the pieces of distance information before and after the reference point in time. Therefore, since the shift amount between the predicted arrival position of moving unit 50 and the target position of moving unit 50 at the reference point in time can be accurately calculated, moving unit 50 can be easily positioned at the target position, and the deterioration in the accuracy of the position control can be suppressed.

In addition, in motor control system 10 according to the exemplary embodiment, moving unit 50 includes head 52 that holds the object and motor 54 that is coupled to head 52 and moves together with head 52, and position detection device 14 includes camera 24 for detecting the position of head 52 and encoder 28 for detecting the position of motor 54.

Accordingly, since the position of head 52 and the position of motor 54 can be detected, even in a case where the position of head 52 and the position of motor 54 are deviated, the position of moving unit 50 at the reference point in time can be accurately calculated. Therefore, since the shift amount between the predicted arrival position of moving unit 50 and the target position of moving unit 50 at the reference point in time can be accurately calculated, moving unit 50 can be easily positioned at the target position, and the deterioration in the accuracy of the position control can be suppressed.

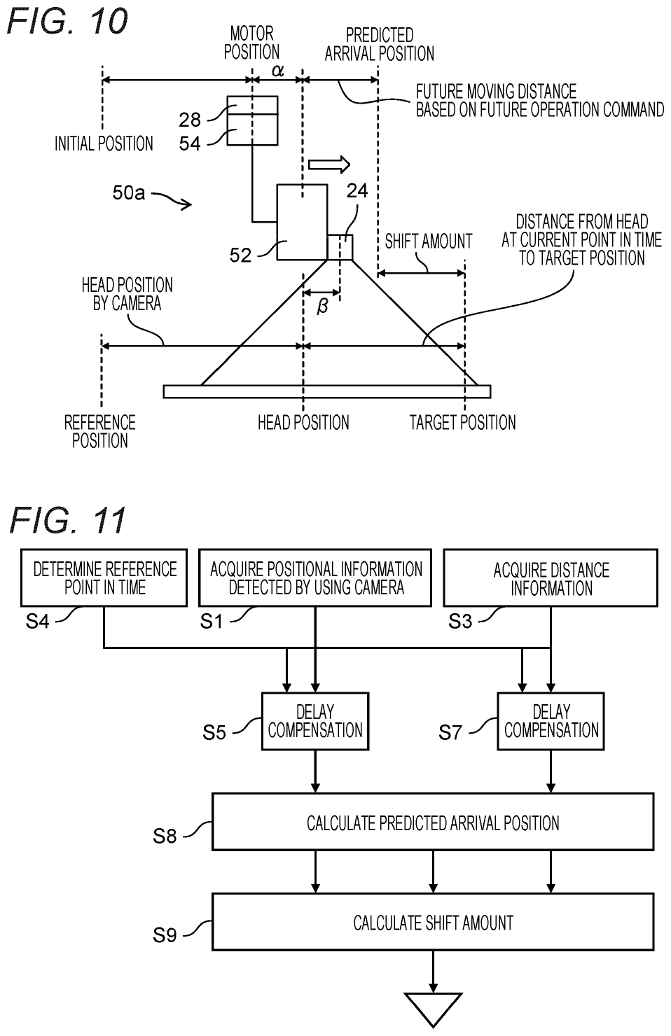

FIG. 10 is a schematic diagram illustrating a schematic configuration of another moving unit 50a.

As illustrated in FIG. 10, in moving unit 50a, head 52 and motor 54 may be coupled by a member having high rigidity such that a distance (see a in FIG. 10) between the position of head 52 and the position of motor 54 does not change.

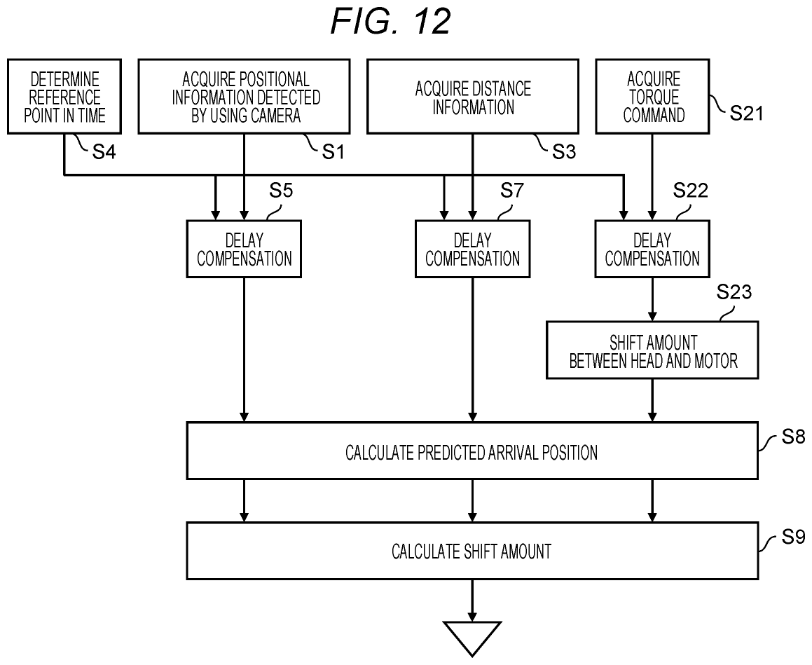

FIG. 11 is a flowchart illustrating a second operation example of shift amount calculation unit 36 of production apparatus 1 in FIG. 1 when the shift amount is calculated.

As illustrated in FIG. 11, shift amount calculation unit 36 may calculate the shift amount between the predicted arrival position of moving unit 50 and the target position of moving unit 50 by using the positional information detected by using camera 24 and the distance information without using the positional information detected by using encoder 28.

FIG. 12 is a flowchart illustrating a third operation example of shift amount calculation unit 36 of production apparatus 1 in FIG. 1 when the shift amount is calculated. As illustrated in FIG. 12, shift amount calculation unit 36 may further acquire a torque command, may calculate the shift amount between the position of head 52 and the position of motor 54 based on the torque command, and may calculate the shift amount between the predicted arrival position of moving unit 50 and the target position of moving unit 50 in further consideration of the shift amount.

For example, position control unit 34 generates and outputs a torque command indicating a drive torque of motor 54 based on the operation command output from controller 12. Shift amount calculation unit 36 acquires the torque command output from position control unit 34 (step S21) and performs delay compensation (step S22). For example, shift amount calculation unit 36 acquires or calculates a torque command at the reference point in time as the delay compensation. Since the calculation of the torque command at the reference point in time is similar to the calculation of the position of moving unit 50 at the reference point in time and the like as described above, the detailed description thereof will be omitted here.

Shift amount calculation unit 36 calculates the shift amount between the position of head 52 and the position of motor 54 at the reference point in time in consideration of the torque command at the reference point in time (step S23). For example, shift amount calculation unit 36 calculates a deformation amount of a coupling member that couples head 52 and motor 54 at the reference point in time in consideration of the torque command at the reference point in time and the rigidity of the coupling member, and calculates the shift amount between the position of head 52 and the position of motor 54 at the reference point in time from the deformation amount.

Shift amount calculation unit 36 calculates the predicted arrival position of moving unit 50 in further consideration of the shift amount between the position of head 52 and the position of motor 54 at the reference point in time (step S8), and calculates the shift amount between the predicted arrival position of moving unit 50 and the target position of moving unit 50 (step S9).

In this manner, shift amount calculation unit 36 calculates the shift amount between the position of head 52 and the position of motor 54 based on the torque command based on the operation command.

Accordingly, since the predicted arrival position of moving unit 50 can be calculated with high accuracy, moving unit 50 can be easily positioned at the target position, and the deterioration in the accuracy of the position control can be suppressed.

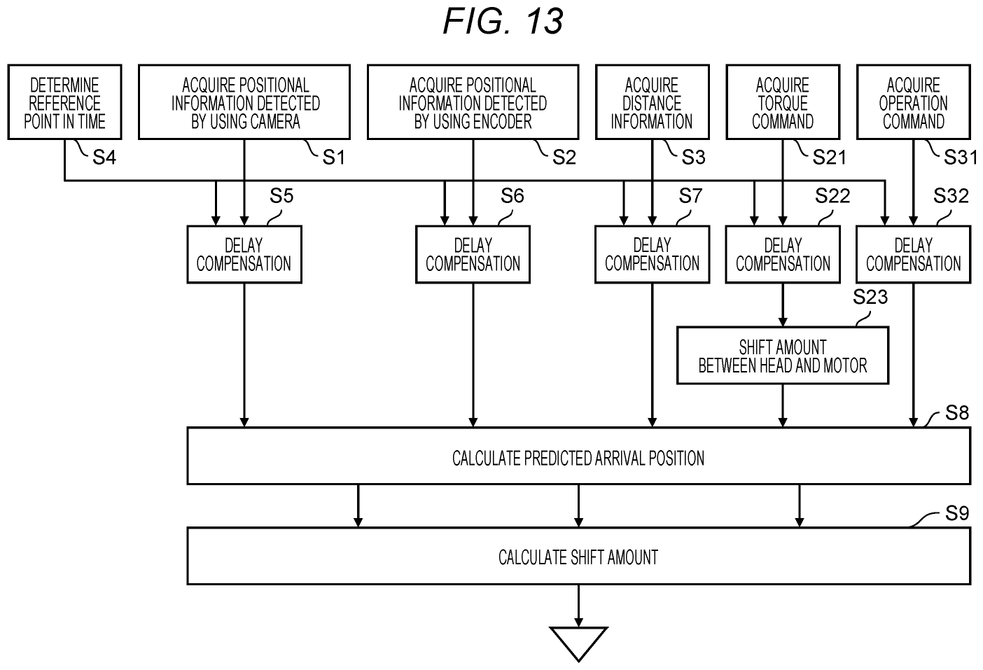

FIG. 13 is a flowchart illustrating a fourth operation example of shift amount calculation unit 36 of production apparatus 1 in FIG. 1 when the shift amount is calculated.

As illustrated in FIG. 13, shift amount calculation unit 36 may further acquire the operation command, and may calculate the shift amount between the predicted arrival position of moving unit 50 and the target position of moving unit 50 in further consideration of the operation command.

For example, shift amount calculation unit 36 acquires the operation command output from controller 12 (step S31) and performs delay compensation (step S32). For example, shift amount calculation unit 36 acquires or calculates the operation command at the reference point in time as the delay compensation. Since the calculation of the operation command at the reference point in time is similar to the calculation of the position and the like of moving unit 50 at the reference point in time as described above, the detailed description thereof will be omitted here.

Shift amount calculation unit 36 calculates the predicted arrival position of moving unit 50 in further consideration of the operation command at the reference point in time (step S8), and calculates the shift amount between the predicted arrival position of moving unit 50 and the target position of moving unit 50 (step S9).

### Other Exemplary Embodiments and the Like

As described above, the exemplary embodiment has been described as an illustration of the techniques disclosed in the present application. However, the technique according to the present disclosure is not limited thereto, and can also be applied to exemplary embodiments or modifications in which changes, replacements, additions, omissions, and the like are made as appropriate without departing from the concept of the present disclosure.

In the above-described exemplary embodiment, the case where motor 54 moves together with head 52 has been described, but the present disclosure is not limited thereto. For example, the motor may not move with the head. In this case, the moving unit does not include the motor.

In addition, in the above-described exemplary embodiment, the case where camera 24 moves together with head 52 has been described, but the present disclosure is not limited thereto. For example, the camera may be fixed at a place where the target position can be imaged.

In addition, general or specific aspects of the present disclosure may be implemented by a system, a device, an apparatus, a method, an integrated circuit, a computer program, or a computer-readable recording medium such as a CD-ROM. In addition, the aspects may be implemented with any combination of the system, the device, the apparatus, the method, the integrated circuit, the computer program, and the recording medium.

For example, the present disclosure may be implemented as the motor control system of the above-described exemplary embodiment. In addition, the present disclosure may be implemented as the control device. In addition, the present disclosure may be implemented as the control method. In addition, the present disclosure may be implemented as a program causing a computer to execute the control method, or may be implemented as a computer-readable non-transitory recording medium in which such a program is recorded.

### INDUSTRIAL APPLICABILITY

The motor control system and the like according to the present disclosure can be used for a control system and the like that move a moving unit by using a motor.

### REFERENCE MARKS IN THE DRAWINGS

10 motor control system
12 controller
14 position detection device
16 motor control device
18 notification device
20 first signal processing circuit
22 first input device
24 camera
26 image processing unit
28 encoder
30 second signal processing circuit
32 second input device
34 position control unit
36 shift amount calculation unit
121 memory

1. A motor control system comprising:
a position detection device that detects a position of a moving unit that moves;
a command device that outputs an operation command for operating a motor that moves the moving unit; and
a control device,
wherein the control device includes
a calculation unit that calculates a predicted arrival position of the moving unit from positional information indicating a position of the moving unit and distance information indicating a future moving distance of the moving unit calculated based on the operation command, and calculates a shift amount between the predicted arrival position and a target position of the moving unit, and
an output unit that outputs information indicating the shift amount between the predicted arrival position and the target position calculated by the calculation unit, and
the calculation unit determines a reference point in time in consideration of at least one of an acquisition time required to acquire the positional information and an acquisition time required to acquire the distance information, acquires or calculates the position and the future moving distance of the moving unit at the reference point in time, and calculates the predicted arrival position based on the acquired or calculated position and future moving distance of the moving unit at the reference point in time.

2. The motor control system according to claim 1, wherein the calculation unit
periodically acquires the positional information and the distance information, and
determines, as the reference point in time, an oldest point in time of a point in time earlier by the acquisition time required to acquire the positional information from a point in time at which latest positional information among a plurality of pieces of the periodically acquired positional information is acquired and a point in time at which latest distance information among a plurality of pieces of the periodically acquired distance information is acquired.

3. The motor control system according to claim 1, wherein the calculation unit
periodically acquires the positional information and the distance information,
determines, as the reference point in time, a point in time earlier by the acquisition time required to acquire the positional information from a point in time at which latest positional information among a plurality of pieces of the periodically acquired positional information is acquired in a case where a period of acquiring the positional information is longer than a period of acquiring the distance information, and
determines, as the reference point in time, a time point in time at which latest distance information among a plurality of pieces of the periodically acquired distance information is acquired in a case where the period of acquiring the distance information is longer than the period of acquiring the positional information.

4. The motor control system according to claim 1, wherein the calculation unit
periodically acquires the positional information, and
calculates the position of the moving unit at the reference point in time by using a latest first point in time before the reference point in time among a plurality of point in times earlier by the acquisition time required to acquire the positional information from a plurality of point in times at which a plurality of pieces of the periodically acquired positional information are acquired, an oldest second point in time after the reference point in time, the positional information acquired at a point in time later by the acquisition time from the latest first point in time, and the positional information acquired at a point in time later by the acquisition time from the oldest second point in time.

5. The motor control system according to claim 1, wherein the calculation unit
periodically acquires the distance information, and
calculates the future moving distance at the reference point in time by using a latest third point in time before the reference point in time among a plurality of point in times at which a plurality of pieces of the periodically acquired distance information are acquired, an oldest fourth point in time after the reference point in time, the distance information acquired at the latest third point in time, and the distance information acquired at the oldest fourth point in time.

6. The motor control system according to claim 1, wherein
the moving unit includes a head that holds an object, and a motor that is coupled to the head and moves with the head, and
the position detection device includes a camera that detects a position of the head, and an encoder that detects a position of the motor.

7. The motor control system according to claim 6, wherein the calculation unit calculates a shift amount between the position of the head and the position of the motor based on a torque command based on the operation command.

8. A control device comprising:
a calculation unit that calculates a predicted arrival position of a moving unit based on positional information indicating a position of the moving unit detected by using a position detection device that detects the position of the moving unit that moves and distance information indicating a future moving distance of the moving unit based on an operation command for operating a motor that moves the moving unit, and calculates a shift amount between the predicted arrival position and a target position of the moving unit; and
an output unit that outputs information indicating the shift amount between the predicted arrival position and the target position calculated by the calculation unit,
wherein the calculation unit determines a reference point in time in consideration of at least one of an acquisition time required to acquire the positional information and an acquisition time required to acquire the distance information, acquires or calculates the position and the future moving distance of the moving unit at the reference point in time, and calculates the predicted arrival position based on the acquired or calculated position or future moving distance of the moving unit at the reference point in time.

9. A control method comprising:
calculating a predicted arrival position of a moving unit based on positional information indicating a position of the moving unit detected by using a position detection device that detects the position of the moving unit that moves and distance information indicating a future moving distance of the moving unit based on an operation command for operating a motor that moves the moving unit, and calculating a shift amount between the predicted arrival position and a target position of the moving unit; and
outputting information indicating the shift amount between the predicted arrival position and the target position calculated in the calculating of the shift amount,
wherein in the calculating of the shift amount, a reference point in time is determined in consideration of at least one of an acquisition time required to acquire the positional information and an acquisition time required to acquire the distance information, the position and the future moving distance of the moving unit at the reference point in time are acquired or calculated, and the predicted arrival position is calculated based on the acquired or calculated position and future moving distance of the moving unit at the reference point in time.

10. A program for causing a computer to execute the control method according to claim 9.
